(19) United States
(12) Patent Application Publication
(10) Pub. No.: US 2007/0114122 A1
(43) Pub. Date: May 24, 2007

(54) Sputtering method and sputtering device

(75) Inventors: Keiji Ishibashi, Tokyo (JP); Shunichi Wakayanagi, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Canon ANELVA Corporation, Fuchu-shi (JP)

(21) Appl. No.: 11/599,058

(22) Filed: Nov. 14, 2006

(30) Foreign Application Priority Data
Nov. 22, 2005 (JP) 337635/2005

(51) Int. Cl. C23C 14/32; C23C 14/00

(52) U.S. Cl. 204/192.1; 204/298.16

(57) ABSTRACT

It is an object of the invention to provide sputtering method and a sputtering device which can provide a uniform film-thickness distribution over the entire area of the substrate. A substrate as an object for a film-forming process and a target formed of a film-forming material are arranged in a container so as to oppose to each other, and a film is formed on a substrate while reciprocating a magnet arranged on the side of the target opposite from the substrate in parallel with the surface of the target, and rotating the substrate by a rotating unit (rotating mechanism). The film is formed while reciprocating the magnet and rotating the substrate by the rotating unit (rotating mechanism) after having set the film-thickness distribution of the thin film formed on the substrate along the longitudinal direction of the magnet to be thicker in the center portion of the substrate than the both end portion thereof.

### BACKGROUND OF THE INVENTION

1. Field of the Invention

The present invention relates to a magnetron sputtering method and a sputtering device and, more specifically, to a technology to obtain a uniform film-thickness distribution.

2. Description of the Related Art

Hitherto, there is a device referred to as “magnetron sputtering device” having a configuration in which a substrate and a target are arranged in a container so as to oppose to each other, and a magnet is arranged on the side of the target opposite from the substrate, so that the magnet is adapted to reciprocate in parallel with the surface of the target. In such a device, a film is formed by depressurizing the interior of the container to form a substantially vacuum state, filling sputtering gas, applying a voltage between the substrate and the target to cause plasma discharge and, in this state, forming a film by sputtering while reciprocating the magnet, so that a large substrate can be supported. In general, in the sputtering device in this configuration, the magnet is adapted to reduce the speed and stop temporarily near returning points because an inertia force acts at the returning points and hence the entire device vibrates each time if the speed of reciprocating motion of the magnet is constant.

In the sputtering device in the related art as describe above, there is a problem such that the period of stay of the reciprocating magnet at both ends of the substrate is relatively long because of the temporary speed reduction and stop near the returning points, and hence the thickness of the film accumulated near both end portions of the substrate is larger than that accumulated in the center portion thereof in the direction of reciprocating motion of the magnet. Therefore, in order to solve the problem as described above, for example, Japanese Unexamined Patent Application Publication No. 2001-172764 discloses a technology to make the thickness of the film accumulated on the substrate uniform by adjusting the T/S distance (the distance between the target and the substrate) according to the position of the reciprocating magnet.

In Japanese Unexamined Patent Application Publication No. 2001-172764, a method to solve the above-described problem by increasing the T/S distance when the magnet is located near the returning points is proposed. However, with this method, it is difficult to achieve uniformity with high degree of accuracy over the entire area of the substrate. In addition, since a process and a device for increasing and decreasing the T/S distance during film forming process are necessary, the sputtering method and the sputtering device inevitably become complicated.

### SUMMARY OF THE INVENTION

Accordingly, it is an object of the invention to provide sputtering method and a sputtering device which can provide a uniform film-thickness distribution with the minimum difference between the largest film thickness and the smallest film thickness over the entire area of a substrate.

A sputtering method according to an aspect of the invention is a sputtering method for forming a film on a substrate by arranging a substrate as an object for forming a film thereon and a target formed of a film material in a container so as to oppose to each other while reciprocating a magnet arranged on the side of the target opposite from the substrate in parallel with the surface of the target, wherein the substrate is rotated by a rotating unit during the film formation.

Preferably, the film is formed while reciprocating the magnet and rotating the substrate by the rotating unit after having set the film-thickness distribution of the film formed on the substrate along the longitudinal direction of the magnet to be thicker in the center portion of the substrate than the both end portion thereof.

Preferably, the distance between the target and the substrate is adjusted by a distance adjusting unit. Preferably, the speed of the reciprocating motion of the magnet is controlled by a speed control unit.

A sputtering device according to an aspect of the invention is a sputtering device having a container that accommodates a substrate as an object for forming a film thereon and a target formed of a film material arranged so as to oppose to each other and a magnet arranged on the side of the target opposite from the substrate so as to reciprocate in parallel with the surface of the target, the sputtering device including a rotating unit that rotates the substrate during the film formation.

Preferably, the sputtering device includes a distance adjusting unit that adjusts the distance between the substrate and the target.

Preferably, the sputtering device includes a speed control unit that controls the speed of reciprocating motion of the magnet.

Preferably, the sputtering device includes a control unit that controls the rotating unit, the distance adjusting unit, and the speed control unit.

Preferably, the sputtering device further includes a storing unit that stores data indicating the distance to be adjusted by the distance adjusting unit and a speed control pattern controlled by the speed control unit, and an input unit that sets the stored data to the control unit.

According to the aspect of the invention, since the substrate is rotated during the film formation, a uniform film-thickness distribution is obtained over the entire area of the substrate.

Since the T/S distance and the speed control pattern of the magnet are controlled, the uniform film-thickness distribution with higher degree of accuracy is obtained.

### BRIEF DESCRIPTION OF THE DRAWINGS

FIG. 1 illustrates a configuration of a sputtering device according to an embodiment of the invention;

FIG. 2A and FIG. 2B illustrate characteristics of a film-thickness distribution in the direction of movement of a magnet (indicated by an arrow A) and the longitudinal direction of the magnet (indicated by an arrow B);

FIG. 3 illustrates characteristics of the relation between the T/S distance and the film-thickness distribution; and

FIGS. 4A to 4C illustrate characteristics of the relation between speed control patterns for the magnet and a film-thickness distribution on the basis of the respective patterns.

### DESCRIPTION OF THE PREFERRED EMBODIMENTS

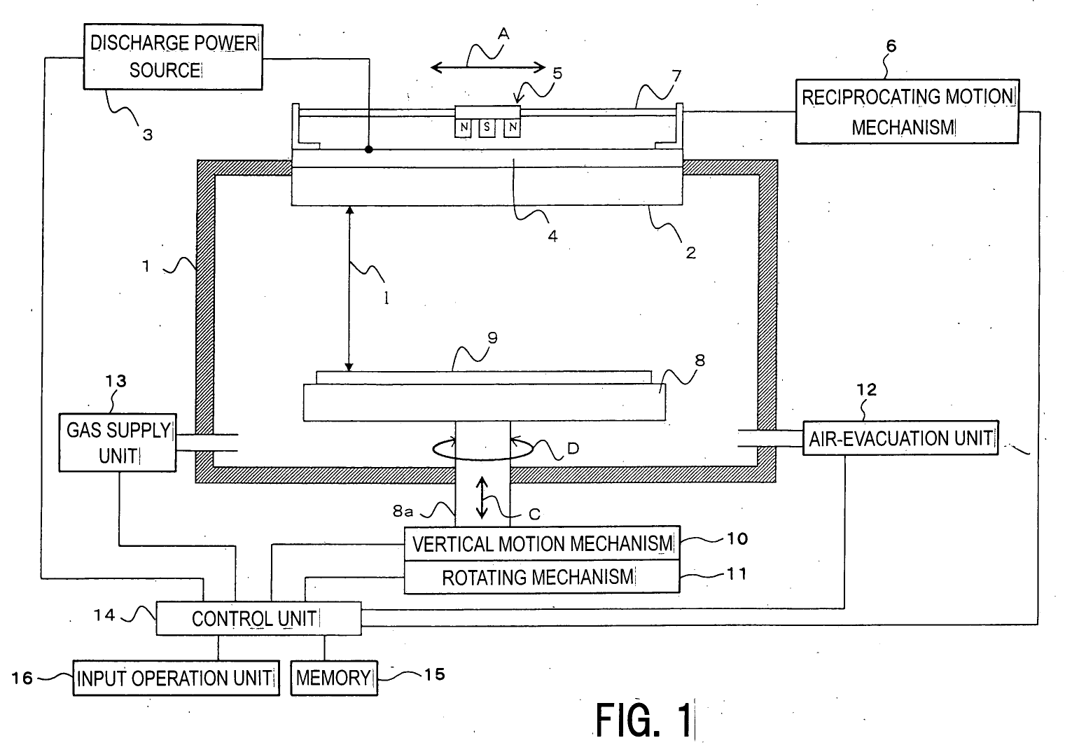

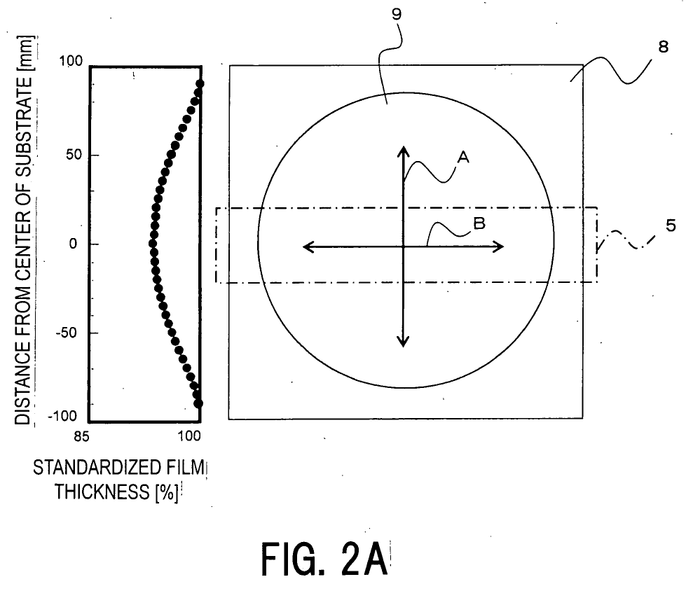

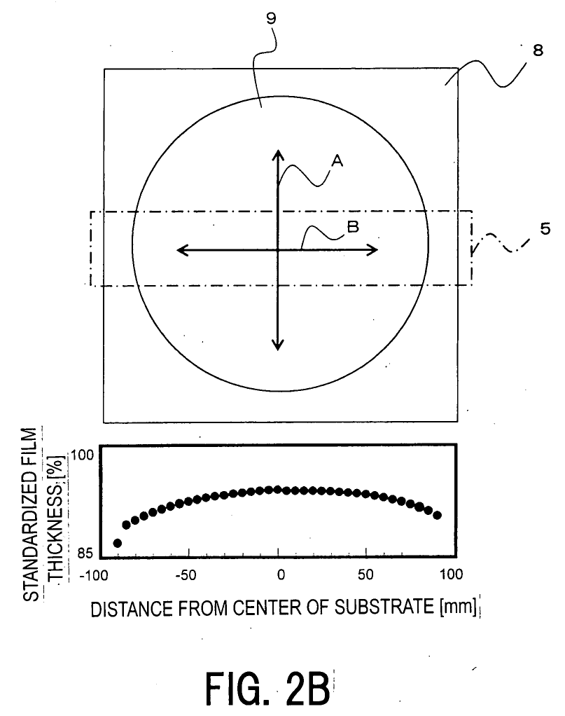

Referring now to the drawings, an embodiment of the invention will be described. FIG. 1 is a conceptual drawing showing a configuration of a portion of a sputtering device relating to an embodiment of the invention; FIG. 2A illustrates characteristics of the film-thickness distribution in the direction of reciprocating motion of the magnet (the direction indicated by an arrow A), and FIG. 2B illustrates characteristics of the film-thickness distribution in the longitudinal direction of the magnet (the direction indicated by an arrow B).

As shown in FIG. 1, a target 2 is provided in the upper portion of a container 1 whose interior is hermetically maintained. The target 2 is formed of a thin film material used for forming a film on a substrate 9, described later, such as A1 as an example. A source power obtained by superimposing a high frequency power on a DC power for plasma discharge is supplied from an external discharge power source 3 via an electrode 4 to the target 2. A magnet 5 is provided on the side of the target 2 opposite from the substrate 9 so as to be capable of reciprocating along a guide shaft 7 in the direction indicated by an arrow A (substantially in parallel with the surface of the target 2) by a reciprocating motion mechanism 6 (including a motor). As shown in FIG. 1 for example, the magnet 5 is configured to have an S-pole arranged at the center and N-poles arranged so as to sandwich the S-pole along the longitudinal direction (the direction indicated by an arrow B in FIG. 2).

A substrate holding member 8 is provided in the lower portion of the container 1 for holding the substrate 9 transported from another container (not shown) which communicates with the container 1 so as to be opposed to the target 2. The substrate 9 is an object to be applied with the film forming process, such as a semiconductor silicon wafer, or liquid crystal substrate. The substrate holding member 8 is supported by a shaft 8a, and is provided so as to be capable of moving vertically in the direction indicated by an arrow C by a vertical motion mechanism 10 (including a motor) as a distance adjusting unit, and capable of rotating in the direction indicated by an arrow D by a rotating mechanism 11 (including a motor) as a rotating unit. In this manner, the distance 1 (T/S distance) between the target 2 and the substrate 9 can be adjusted by the vertical motion of the substrate holding unit 8 in the direction indicated by the arrow C by the vertical motion mechanism 10. A shield member (not shown) is provided so as to surround a space formed by the target 2 and the substrate 9 to define a discharging space.

An air-evacuation unit 12 that brings the interior of the container 1 into a vacuum state, and a gas supply unit 13 that supplies sputtering gas such as N2+Ar into the container 1 in the vacuum state are provided. The reciprocating motion mechanism 6, the vertical motion mechanism 10, the rotating mechanism 11, the air-evacuation unit 12, and the gas supply unit 13 are controlled in timing of operation or the like respectively by a control unit 14. The control unit 14 controls the discharge power source 3. Control data such as T/S distance 1 or the speed control pattern for the magnet 5 is stored in a memory 15 in advance. An input operation unit 16 is used for setting of the control data in the memory 15 and other predetermined input operations by an operator.

Subsequently, the invention will be described in principle. As described above, in the sputtering device in the related art, there is the problem such that the film thickness at the both end portions of the substrate 9 is larger than that in the center portion thereof since the period of stay of the reciprocating magnet 5 at the both ends of the substrate 9, which corresponds to portions near the returning points thereof, is relatively long. FIG. 2A shows a film-thickness distribution on the disk-shaped substrate 9 with respect to the direction of movement of the magnet 5 in the related art. As shown in the drawing, the thickness distribution is represented by a depressed (concave shaped) curve in which the film thickness is increased at the both end portions of the substrate 9 and is decreased in the center portion thereof.

In order to solve the above-described problem, for example, the T/S distance 1 is adjusted in advance in the state in which the magnet 5 is standstill so that the film-thickness distribution (FIG. 2B) which traces a chevron-wise (convex shaped) curve in the longitudinal direction of the magnet 5 (the direction indicated by the arrow B in FIG. 2) is achieved for cancelling the depressed curve (FIG. 2A) in the direction of reciprocating motion (the direction indicated by the arrow A in FIG. 2) of the magnet 5. Subsequently, the film formation is performed while moving the magnet 5 reciprocally, rotating the substrate 9, and controlling the speed of the reciprocating motion of the magnet 5 to achieve a uniform film-thickness distribution.

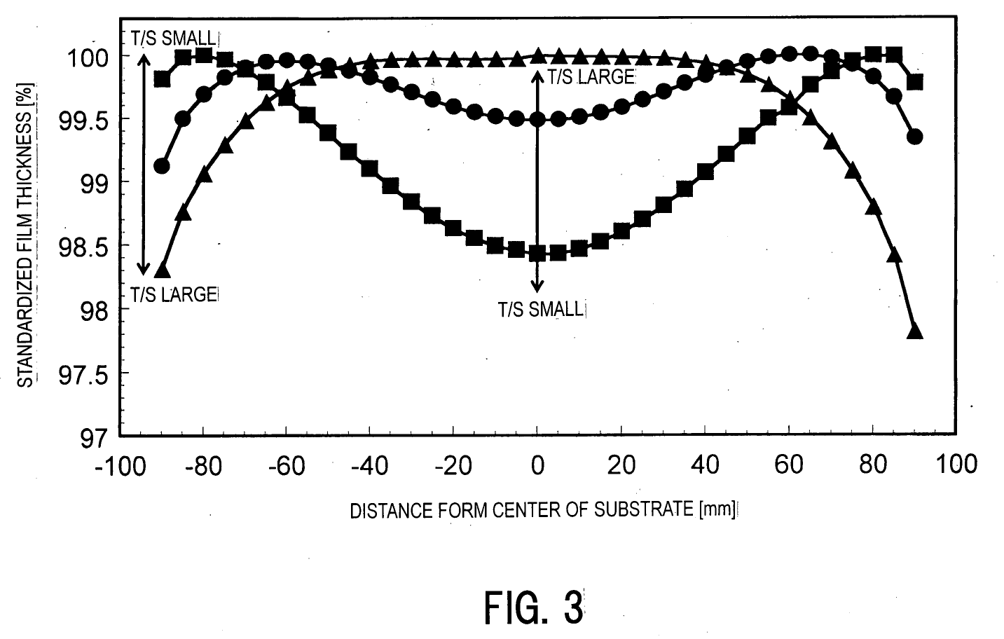

In general, the T/S distance and the shape of the film-thickness distribution can be adjusted as follows. FIG. 3 is a drawing showing a variation of the film-thickness distribution resulted by changing the T/S distance 1. The vertical axis represents a standardized film thickness, and the lateral axis represents the distance from the center of the substrate 9. In general, as shown by solid squares in FIG. 3, the film-thickness distribution on the substrate 9 is such that the thickness of the film in the center portion decreases and that in the edge portion increases as the T/S distance 1 decreases. In contrast, when the T/S distance 1 is gradually increased, the film-thickness distribution assumes a curve indicated by solid circles in FIG. 3. In this case, the difference between the portion where the film-thickness is thin (the center portion) and the portion where the film thickness is thick (edge portion) falls within 1%, which is a preferable state. When the T/S distance 1 is further increased, the film-thickness distribution assumes a curve indicated by solid triangles in FIG. 3, which is flat only in the center portion.

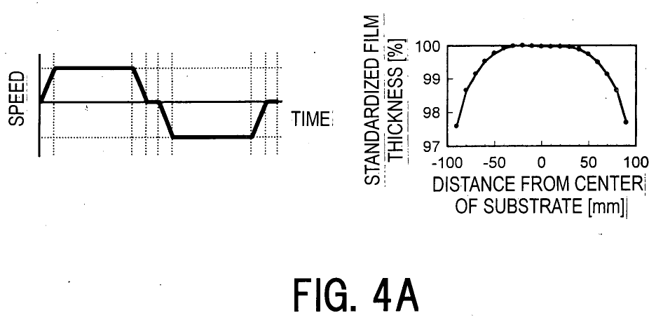

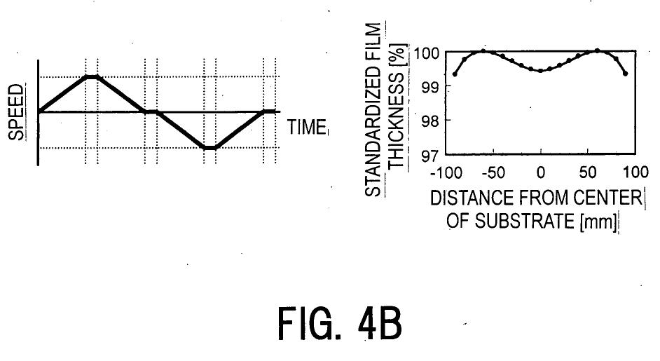

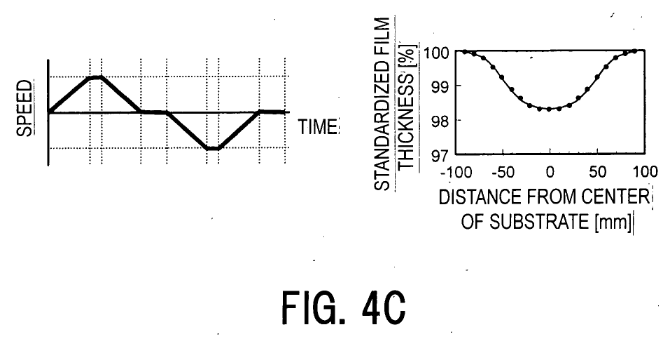

FIGS. 4A, 4B, 4C illustrate the relations between the speed control patterns for one reciprocating motion of the magnet 5 and the film-thickness distributions on the substrate on the basis of the respective patterns. As shown in FIGS. 4A, 4B and 4C, the film thickness on the substrate 9 can be changed in the center portion (the depth of the depression of the film-thickness distribution curve) and in the edge portion by changing the periods of acceleration, constant velocity, and deceleration of the magnet 5 respectively. Therefore, adjustment can be made to increase the period of stay of the magnet in the area where the film-thickness is thin by reducing the speed and decrease the period of stay of the magnet in the area where the film-thickness is thick by increasing the speed. A plurality of the speed control patterns as described above are stored in the memory 15 so that the operator can select through the input operation unit 16, and the speed control unit includes at least the memory 15 in which the speed control patterns as described above are stored and the control unit 14 that controls the reciprocating motion mechanism 6 on the basis of the speed control pattern.

An actual film-forming operation according to the embodiment shown above will be as shown below.

The substrate 9 transported from an another container (not shown) which communicates with the container 1 is held by the substrate holding unit 8 in the container 1, and the interior of the container 1 is depressurized by operating the air-evacuation unit 12, and then gas is supplied to the container 1 by operating the gas supply unit 13 to bring the interior of the container 1 to a predetermined pressure. Subsequently, the magnet 5 is moved to the center portion of the target 2 and brought into a halt and, in this state, the discharge power source 3 is operated, and a predetermined voltage is supplied between the target 2 and the substrate 9. Accordingly, a plasma discharge occurs in the discharge space, and the film-forming process by sputtering is performed. Then, the film-thickness distribution of the substrate 9 along the longitudinal direction of the magnet 5 is measured to confirm that the chevron-shaped (convex shaped) curve as shown in FIG. 2B is obtained.

Subsequently, the film-forming process is performed while reciprocating the magnet 5 at a predetermined speed by the reciprocating motion mechanism 6, and rotating the substrate 9 at a predetermined speed by the rotating mechanism 11. Then, the film-thickness distribution from the center of the substrate 9 in the radial direction is measured at an adequate timing. Then, whether the film-thickness in the center portion of the substrate is the same as the peripheral portion of the substrate is determined from the result of measurement. If not, the speed control pattern of the magnet 5 is selected, for example, from FIG. 4. In this case, the speed control pattern which increases the speed for the portion where the film-thickness is large, and decreases the speed for the portion where the film-thickness is small is selected. Then, the film-formation is performed while rotating the substrate 9 by controlling the speed of the magnet 5 using the selected speed control pattern. The measurement of the film-thickness distribution is performed, for example, by using a known ellipsometer.

As an example, conditions of film formation to obtain a film of 1 μm in thickness by aluminum nitride AlN are as follows.
Substrate: Si substrate of φ150 mm
Sputtering Gas: 80% N2+Ar
Pressure in Container: 0.08 Pa
Discharge Power: RF4.8 kW+DC 4.5 kW
T/S Distance: 94 mm
Substrate Temperature: about 300° C.
Number of Revolutions of Substrate: 32 rpm
Frequency of Reciprocal Motion of Magnet: approx. 0.5 Hz

When the setting as shown above is finished, large quantities of film-formed substrates having uniform film-thickness distribution with high degree of accuracy can be manufactured easily by repeating the film-forming process for other substrate while maintaining the setting contents such as the T/S distance and the speed control pattern.

According to the embodiment of the invention described thus far, the uniform film-thickness distribution can be obtained by cancelling the film-thickness distribution in the longitudinal direction and the direction of the reciprocating motion of the magnet 5 by rotating the substrate 9 during the film formation.

In this case, although a slight nonuniformity remains in the radial direction of the substrate 9, this nonuniformity can be solved by minute-adjustment of the T/S distance 1 and the speed control pattern of the magnet 5, and the uniformity of the film-thickness distribution with higher degree of accuracy can be achieved.

Since the adjustment of the T/S distance 1 and the speed control patterns for the reciprocating motion of the magnet 5 may be stored as numerical values in the memory 15 in advance so that they can be selected from these numerical values at the time of the film formation, the operation is very easy.

An experimental data relating to the uniformity of the film thickness distribution obtained by the sputtering method according to the invention was obtained as follows. A substrate of 150 mm in diameter was used, and the film thickness was measured at 228 points in total on the substrate from the center to 90 mm by 5 mm pitches in the radial direction at every 30° in rotational angle in the rotating direction, that is, along 12 diameters in total (217 points when the center is counted as one point). On the basis of the result, a standard deviation a of the film-thickness distribution for the above-described 228 points was obtained by an expression (1).

According to the result of the experiment under the conditions described above, the value three times the standard deviation σ, 3σ=0.39% could be obtained, and hence it is proved that the uniform film-thickness distribution with high degree of accuracy is obtained over the entire area of the substrate.

The power for the plasma discharge or the configuration of the reciprocally moving magnet used for the description of the sputtering device according to the present embodiment is illustrative only, and the invention is not limited thereto. For example, when the material as the object of sputtering is metal, the DC power or the high-frequency power is employed as the power for the plasma discharge power, and the magnet is not limited to those magnetized into poles of N-S-N (or S-N-S). Therefore, the invention may be modified into various modes without departing from a technical scope stated in the appended claims.

What is claimed is:

1. A sputtering method for forming a film on a substrate by arranging a substrate as an object for forming a film thereon and a target formed of a film material in a container so as to oppose to each other while reciprocating a magnet arranged on the side of the target opposite from the substrate in parallel with the surface of the target,
wherein the substrate is rotated by a rotating unit during the film formation.

2. The sputtering method according to claim 1, wherein the film is formed while reciprocating the magnet and rotating the substrate by the rotating unit after having set the film-thickness distribution of the film to be formed on the substrate along the longitudinal direction of the magnet to be thicker in the center portion of the substrate than the both end portion thereof.

3. The sputtering method according to claim 1, wherein the distance between the target and the substrate is adjusted by a distance adjusting unit.

4. The sputtering method according to claim 1, wherein the film is formed while reciprocating the magnet and rotating the substrate by the rotating unit after having set the film-thickness distribution of the film to be formed on the substrate along the longitudinal direction of the magnet to be thicker in the center portion of the substrate than the both end portion thereof, and the distance between the target and the substrate is adjusted by a distance adjusting unit.

5. The sputtering method according to claim 1, wherein the speed of the reciprocating motion of the magnet is controlled by a speed control unit.

6. The sputtering method according to claim 1, wherein the film is formed while reciprocating the magnet and rotating the substrate by the rotating unit after having set the film-thickness distribution of the film to be formed on the substrate along the longitudinal direction of the magnet to be thicker in the center portion of the substrate than the both end portion thereof, and the speed of the reciprocating motion of the magnet is controlled by a speed control unit.

7. The sputtering method according to claim 1, wherein the distance between the target and the substrate is adjusted by a distance adjusting unit and the speed of the reciprocating motion of the magnet is controlled by a speed control unit.

8. The sputtering method according to claim 1, wherein the film is formed while reciprocating the magnet and rotating the substrate by the rotating unit after having set the film-thickness distribution of the film to be formed on the substrate along the longitudinal direction of the magnet to be thicker in the center portion of the substrate than the both end portion thereof, the distance between the target and the substrate is adjusted by a distance adjusting unit, and the speed of the reciprocating motion of the magnet is controlled by a speed control unit.

9. A sputtering device having a container that accommodates a substrate as an object for forming a film thereon and a target formed of a film material arranged so as to oppose to each other and a magnet arranged on the side of the target opposite from the substrate so as to reciprocate in parallel with the surface of the target, the sputtering device including a rotating unit that rotates the substrate during the film formation.

10. The sputtering device according to claim 9, comprising a distance adjusting unit that adjusts the distance between the substrate and the target.

11. The sputtering device according to claim 9, comprising a speed control unit that controls the speed of reciprocating motion of the magnet.

12. The sputtering device according to claim 9, comprising a distance adjusting unit that adjusts the distance between the substrate and the target, and a speed control unit that controls the speed of reciprocating motion of the magnet.

13. The sputtering device according to claim 9, comprising:
a distance adjusting unit that adjusts the distance between the substrate and the target;
a speed control unit that controls the speed of reciprocating motion of the magnet; and
a control unit that controls the rotating unit, the distance adjusting unit, and the speed control unit.

14. The sputtering device according to claim 9, comprising:
a distance adjusting unit that adjusts the distance between the substrate and the target;
a speed control unit that controls the speed of reciprocating motion of the magnet; and
a control unit that controls the rotating unit, the distance adjusting unit, and the speed control unit;
a storing unit that stores data indicating the distance to be adjusted by the distance adjusting unit and a speed control pattern controlled by the speed control unit, and
an input unit that sets the stored data to the control unit.
